(19) United States
(12) Patent Application Publication
(10) Pub. No.: US 2005/0258837 A1
(43) Pub. Date: Nov. 24, 2005

(54) Press-connecting pliers for electric communication terminals on transmitting lines for phone and network

(75) Inventors: Chih-Lang Wang, Taipei Hsien (TW); Chien-Chou Liao, Taipei Hsien (TW)

Correspondence Address: BACON & THOMAS, PLLC, 625 SLATERS LANE, FOURTH FLOOR, ALEXANDRIA, VA, 22314, US

(73) Assignee: Hanlong Industrial Co., Ltd., Taipei Hsien (TW)

(21) Appl. No.: 10/847,872

(22) Filed: May 19, 2004

(51) Int. Cl. G01R 31/04

(52) U.S. Cl. 324/538

(57) ABSTRACT

The press-connecting pliers mainly comprises a main body, a testing unit and an electric power supplying unit; the main body at least has a press-connecting slot for press connecting of an electric communication terminal and a transmitting line; the testing unit is provided in the main body and comprises an electric circuit board, a testing insertion groove and an indicating unit for the purpose of examining whether the communication terminal is electrically connected after press connecting, and using the electric power supplying unit to supply electric power required by the testing unit. Thereby, after press connecting of the electric communication terminal using the press-connecting slot, it is convenient to examine whether the communication terminal is electrically connected after press connecting directly through the testing unit.

### BACKGROUND OF THE INVENTION

1. Field of the Invention

The present invention is related to a pair of press-connecting pliers for electric communication terminals on transmitting lines for a telephone and a network, and especially to a pair of press-connecting pliers provided both for press connecting and testing, thereby a user can be aware of whether an electric communication terminal is electrically connected after fast proceeding of press connecting and testing of the electric communication terminal.

2. Description of the Prior Art

Generally, a telephone communication line or a transmitting line of a network has on both ends thereof a communication terminal (such as RJ-45), the communication terminal is provided therein with a plurality of pins, when the two ends of the abovementioned lines of the communication terminal are respectively insertion connected to a transmitting end and a receiving end for connecting, an effect of transmission can be acquired through the signal transmitting of the pins.

However, in connecting the communication terminal of a common transmitting line, plural fine core wires must be pressed and respectively electrically connected with plural pins in the communication terminal, the volume of the fine corewires is very small, they must be press connected by means of a specific press-connecting tool for assembling.

When in mass production of transmitting lines, a specific testing unit is needed to test in order to assure superiority of the transmitting lines. However, during the process of line connecting, constructing workers in site generally need to suitably change the lengths of the transmitting lines for line connecting in pursuance of the size of the circumference space of the site.

The lengths changed of the transmitting lines must be that, at least an electric communication terminal at one end of each transmitting line is cut out, and the desired length of each is measured, then a new communication terminal is reconnected thereto; during the process of assembling, by virtue that the volume of the communication terminal is very small, and the inner pins thereof must be accurately contact with the fine core wires in the lines for connecting with the lines, hence a specific press-connecting tool must be used for working of the press-connecting pliers. However, in working, it always is unable to know whether the electrically connection of a transmitting line is surely connected with the pins of the communication terminal; the communication terminal that has well press connected with the two ends of the transmitting line must be connected respectively to a transmitting end and a receiving end for testing, this may make inconvenience of the constructing of the workers in the site. Therefore, the inventor of the present invention planned to study and find a way to solve the problem stated.

The inventor found a U.S. Pat. No. 4,736,480 concerning a pair of press-connecting pliers during his studying process, it was mentioned in the patent that an insertion socket was provided on the bottom of a handle on one end of the press-connecting pliers to allow insertion of an audio plug for testing.

Another U.S. Pat. No. 2,023,916 concerning a pair of tool pliers, it is mentioned in the patent that two handles are respectively provided on their bottom ends with an electrically connecting portion, one handle on one end is provided with a light emitting resistance, so that the tool pliers can be put on fuses respectively by means of the two handles to test whether electric currents pass through the fuses.

Further there is a British patent No. GB2,120,797A concerning a pair of hardness testing pliers; it mainly is provided in the pliers with an electric circuit control unit, and provided outside of the pliers with a display area, so that when in proceeding to the hardness test, the display area shows the value of hardness.

The above stated prior arts that have been published have their respective features in use, but they do not simply have any measure to solve the problem that the present invention is to solve; i.e.: to provide a measure of solving for convenient press-connecting in constructing and testing specifically for a pair of press-connecting pliers for electric communication terminals on transmitting lines for a telephone and a network in press-connecting and the testing step thereafter.

### SUMMARY OF THE INVENTION

In view of the inconvenience stated above resided in the above conventional constructing work of press-connecting pliers, the inventor of the present invention successfully developed the pair of press-connecting pliers on transmitting lines for electric communication terminals for a telephone and a network that can get rid of the problems resided in the conventional press-connecting pliers.

Whereas, the press-connecting pliers on transmitting lines for electric communication terminals for a telephone and a network of the present invention mainly comprises a main body, a testing unit and an electric power supplying unit, wherein the main body at least has a press-connecting slot for press connecting of an electric communication terminal and a transmitting line; the testing unit is provided in the main body and comprises an electric circuit board, a testing insertion groove and an indicating unit for the purpose of examining whether the electric communication terminal is electrically connected after press connecting, and for the purpose of using the electric power supplying unit to supply electric power required by the testing unit. Thereby, after press connecting of the electric communication terminal using the press-connecting slot, we can examine whether the electric communication terminal is electrically connected after press connecting directly through the testing unit.

The object of the present invention is resided in: by providing the press-connecting slot and the testing unit in the main body, the entire press-connecting pliers can be in both the states of press connecting and examining the state of electric connecting of the electric communication terminal; so that the workers in site can fast proceed to distribution of transmitting lines.

The present invention will be apparent in its content and its effect to be achieved after reading the detailed description of the preferred embodiment thereof in reference to the accompanying drawings.

### BRIEF DESCRIPTION OF THE DRAWINGS

FIG. 1 is a schematic view showing a pair of press-connecting pliers of the present invention;

FIG. 2 is an analytical perspective view of the press-connecting pliers of the present invention;

FIG. 3 is a front view of the press-connecting pliers of the present invention;

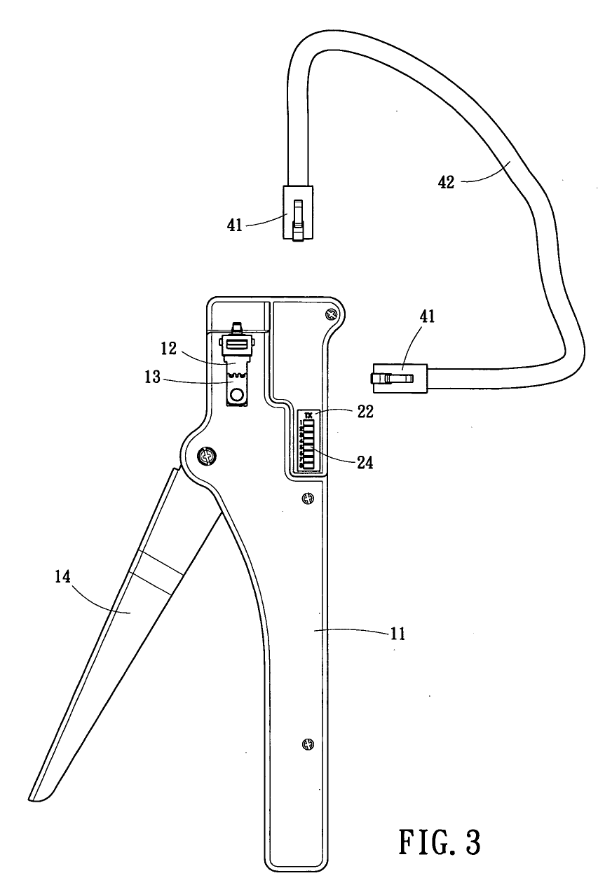

FIG. 4 is a perspective view of the second embodiment of the present invention;

FIG. 5 is a perspective view of the third embodiment of the present invention;

FIG. 6 is a perspective view of the fourth embodiment of the present invention.

### DETAILED DESCRIPTION OF THE PREFERRED EMBODIMENT

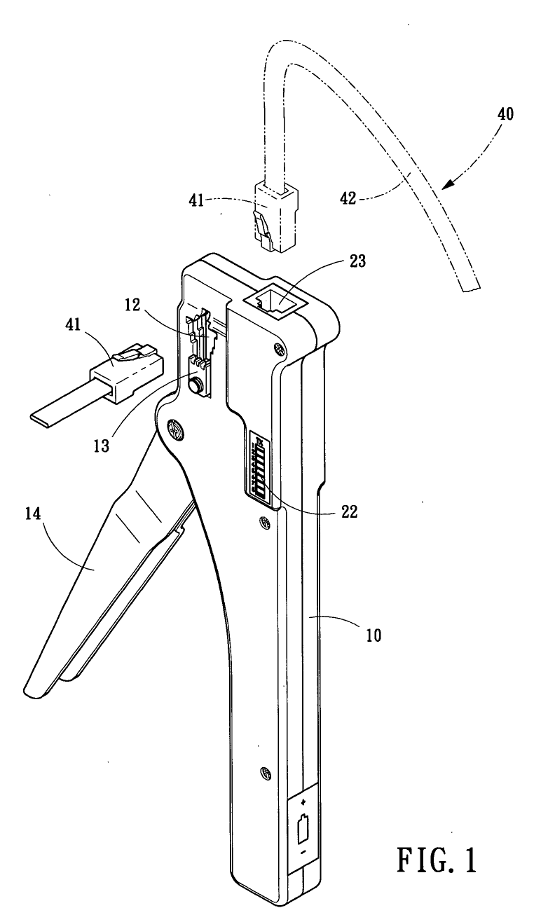

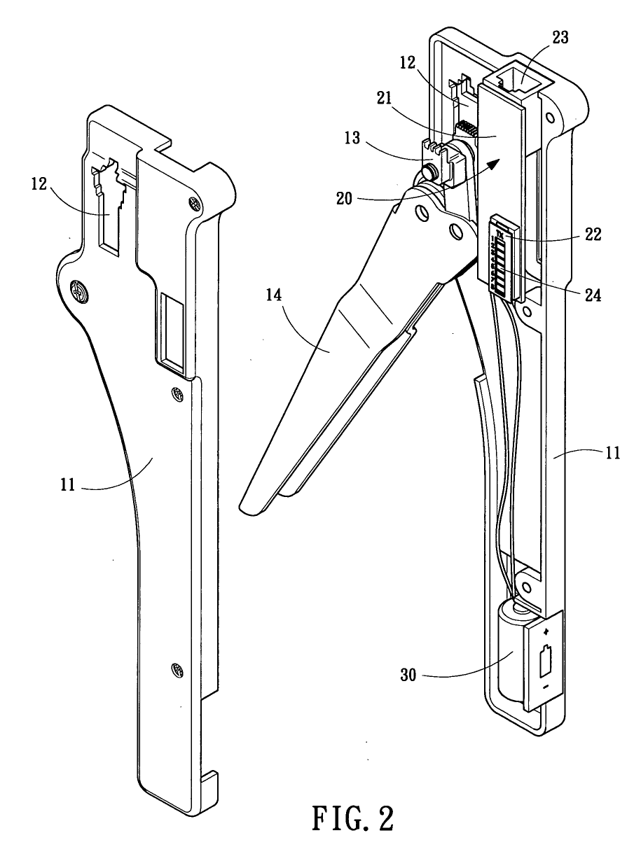

As shown in FIGS. 1 and 2, the press-connecting pliers on transmitting lines for electric communication terminals for a telephone and a network of the present invention mainly comprises a main body 10, a testing unit 20 and an electric power supplying unit 30, wherein:
the main body 10 is composed of two mutually opposite covers 11, and the two mutually opposite covers 11 are each provided with a press-connecting slot 12; a press-connecting unit 13 is provided at the press-connecting slots 12 to link up with a press handle 14;
the testing unit 20 is provided between the two covers 11, and is composed of an electric circuit board 21, an indicating unit 22 and at least a testing insertion groove 23; the indicating unit 22 and the testing insertion groove 23 are provided on the electric circuit board 21 and are provided in a raised mode on the two covers 11; the testing insertion groove 23 is provided for insertion of an electric communication terminal 41, while the indicating unit 22 in this embodiment of the present invention is an LED;
the electric power supplying unit 30 is provided between the two covers 11, and is connected with the testing unit 20.

Thereby, in FIG. 1 which shows an example with a testing insertion groove 23, a transmitting line 40 and the electric communication terminal 41 are inserted into the press-connecting slots 12, then the press-connecting unit 13 is moved by means of the press handle 14 to do press connecting of the transmitting line 40 with the electric communication terminal 41, so that the inner pins of the electric communication terminal 41 and fine core wires in the transmitting line 40 are mutually press connected; while the transmitting line 40 and the electric communication terminal 41 after press connecting are inserted into the testing insertion groove 23, the other end of them is insertion connected to an output terminal such as of a MODEM (not shown), the electric communication terminal 41 inserted into the testing insertion groove 23 can thus be examined via the electric circuit board 21 to see whether the transmitting line 40 is electrically connected normally with the electric communication terminal 41; and the indicating unit 22 can indicate the state of electric connection of the transmitting line 40 with the electric communication terminal 41, thereby the problem of the conventional way that the transmitting line 40 is connected respectively to a transmitting end and a receiving end for being aware of whether the transmitting line 40 and the electric communication terminal 41 are mutually electrically connected can be solved.

Referring to FIGS. 1 2 and 3 which shows an example with two testing insertion grooves 23, two electric communication terminals 41 on two ends of a transmitting line 40 are inserted respectively into the two testing insertion grooves 23; at this time, by virtue that an electric circuit board 21 of a testing unit 20 is connected with an electric power supplying unit 30 and is supplied with electric power by the electric power supplying unit 30, by operation of the electric circuit board 21, the electric communication terminals 41 on two ends of the transmitting line 40 can be tested to see whether the two electric communication terminals 41 on the two ends of the transmitting line 40 are mutually electrically connected with each other.

By the fact that an indicating unit 22 on the electric circuit board 21 is controlled by the electric circuit board 21, while the indicating unit 22 of the present invention is formed from LEDs' 24 of different colors, after operation of the electric circuit board 21 for testing whether the two electric communication terminals 41 on the two ends of the transmitting line 40 are mutually electrically connected with each other, the indicating unit 22 can let a user know by presenting different colors, so that the user can fast distinguish the state of electric connection among the transmitting line 40 and the electric communication terminal 41, to thereby judge whether the work of press connecting is correct.

The indicating unit 22, in addition to being the embodiment formed from LEDs' 24 of different colors, can also be an embodiment of having an element such as a buzzer with the function of indicating convenient for use of a user.

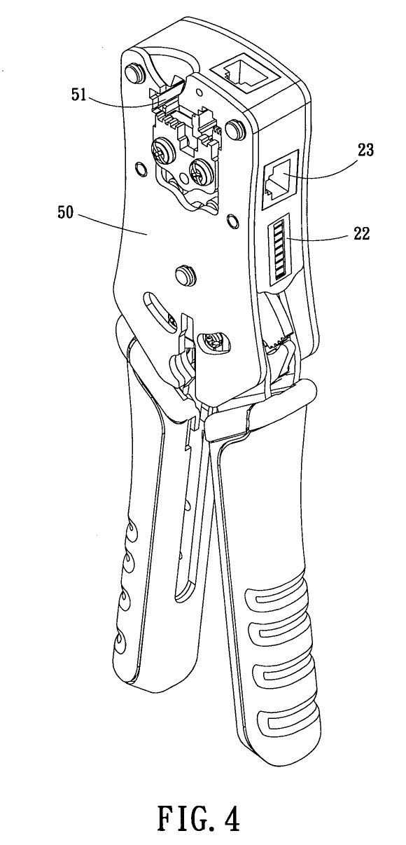

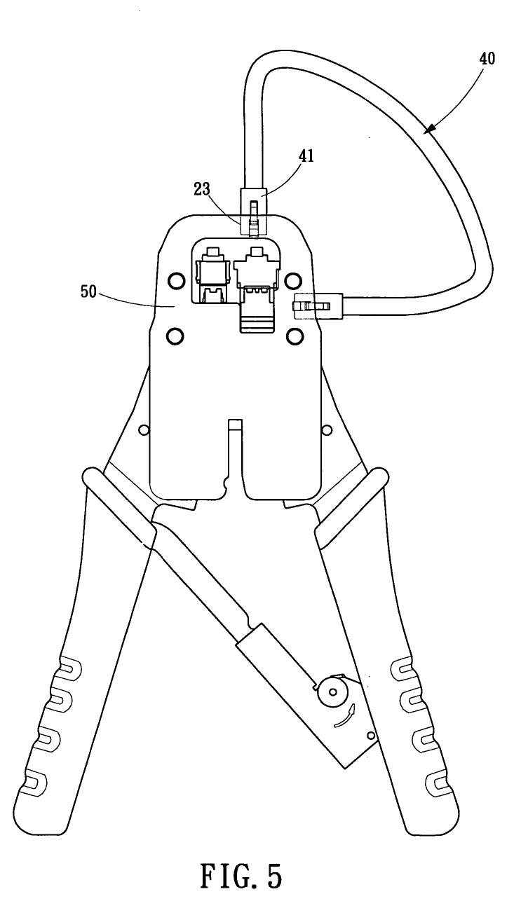

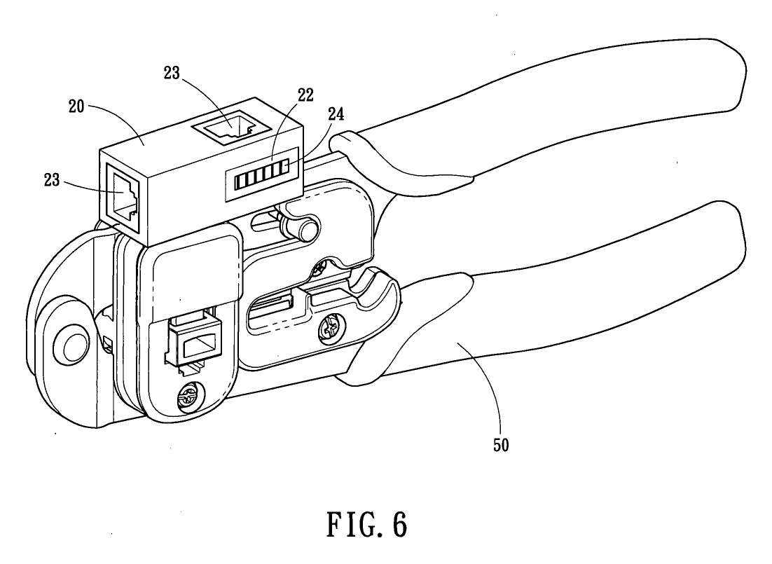

However, the present invention is applicable on a pair of press-connecting pliers 50 of a different specification, such as are shown in FIGS. 4 and 5, the press-connecting pliers 50 is provided with press-connecting slots 51 of a different specification, wherein the sizes of testing insertion grooves 23 are also suitably varied in pursuance of the size of the press-connecting slots 51 in order to suit press-connecting pliers 50 of various types, and two electric communication terminals 41 on two ends of a transmitting line 40 are inserted respectively into the testing insertion grooves 23 for testing; and referring to FIG. 6, the testing unit 20 is also provided on the outer wall of the press-connecting pliers 50 and is also provided with an indicating unit 22 and testing insertion grooves 23, while the indicating unit 22 is formed from LEDs' 24. However, the present invention only takes the above stated embodiments for illustration, variations applied on the press-connecting pliers 50 shall fall within the scope of protection of the present invention.

The names of the members composing the present invention and shown in the drawings are only for illustrating the present invention and not for giving any limitation to the scope of the present invention. It will be apparent to those skilled in this art that various equivalent modifications or changes without departing from the spirit of this invention shall also fall within the scope of the appended claims.

1. A pair of press-connecting pliers for electric communication terminals on transmitting lines for a telephone and a network, said press-connecting pliers comprises:
a main body, said main body at least has a press-connecting slot, a press-connecting unit is provided at said press-connecting slot to link up with a press handle;
a testing unit provided in said main body, and comprises an electric circuit board, an indicating unit and at least a testing insertion groove, said indicating unit and said testing insertion groove are provided on said electric circuit board and are separately provided on said main body; and
an electric power supplying unit, provided in said main body and is connected with said testing unit;
with the above elements, after press connecting of said electric communication terminal using said press-connecting slot, examination is done whether said electric communication terminal is electrically connected through said testing unit.

2. The pair of press-connecting pliers for electric communication terminals on transmitting lines for a telephone and a network as defined in claim 1, wherein said main body is composed of two mutually opposite covers.

3. The pair of press-connecting pliers for electric communication terminals on transmitting lines for a telephone and a network as defined in claim 1, wherein said indicating unit is an LED.

4. The pair of press-connecting pliers for electric communication terminals on transmitting lines for a telephone and a network as defined in claim 1, wherein said indicating unit is formed from more than two LEDs' of different colors.

5. The pair of press-connecting pliers for electric communication terminals on transmitting lines for a telephone and a network as defined in claim 1, wherein said indicating unit is a buzzer with a function of indicating.
